(19) United States
(12) Patent Application Publication
(10) Pub. No.: US 2019/0189840 A1
(43) Pub. Date: Jun. 20, 2019

(54) METHOD OF TRANSFERRING NANOSTRUCTURES AND DEVICE HAVING THE NANOSTRUCTURES

(71) Applicant: NATIONAL CHENG KUNG UNIVERSITY, Tainan City (TW)

(72) Inventor: Shu-Ju Tsai, Tainan City (TW)

(21) Appl. No.: 15/845,493

(22) Filed: Dec. 18, 2017

(51) Int. Cl. H01L 33/06; H01S 5/10; H01L 41/16; H01L 33/34; H01L 31/0352; H01L 33/00; H01L 33/32

(52) U.S. Cl. CPC H01L 33/06; H01S 5/1067; H01L 41/16; H01L 33/32; H01L 31/035227; H01L 33/0075; H01L 33/0054; H01L 33/34

(57) ABSTRACT

An illustrative method for transferring nanostructures is provided with the steps of: forming a two-dimensional material (2D material) on a first substrate; forming a plurality of nanostructures on the 2D material; bonding a surface of one or more of the plurality of nanostructures with a head or a second substrate, and/or shaking the one or more nanostructures with or without a fluid; and separating the one or more nanostructures from the 2D material.

### BACKGROUND OF THE INVENTION

### 1. Field of the Invention

The present invention relates to methods for transferring nanostructures and devices having the transferred nanostructures.

### 2. Description of Related Art

Devices with physical flexibility and stretchability have attracted a great deal of interest for use in wearable electronic technology and large-area electronics, including displays, energy harvesters, energy storage devices, distributed sensor networks, and Internet of Things applications [1]. Moreover, the flexibility is a key factor for enhancing the performance for piezoelectric devices, such as piezoelectric transistors [2], self-powered nanogenerators [3,4], sensors [5,6], and piezo-phototronic effect enhanced solar cells [7,8] and light-emitting diodes [9] driven by the mechanical energy from the environment. One-dimensional semiconductors, i.e., nanorods (NRs) or nanowires (NWs), are promising for flexible device applications, because these structures represent the most effective route for obtaining a high maximum flexion and maintaining high performance under strain and deformation. [3,10-12] Single-crystal III-nitride nanorods are one of the most important semiconductors due to their tunable and direct band gap, good chemical stability, tunable electrical structure, and great piezoelectrical characteristics for a large number of applications, such as piezoelectric nanogenerators,[13] nanolasers,[14,15] photodetectors,[11] photovoltaic cells,[16] and hydrogen generation.[17-19] High-quality single-crystalline III-nitride nanorods are typically epitaxied at high temperatures on rigid single-crystalline Si (111), sapphire, and SiC substrates, but these substrates cannot be adapted for flexible electronics or some applications. For flexible applications, high-quality of GaN nanorods have been grown on highly crystalline single- or few-layer of transferred graphene on bulk substrates,[20,21] and then the Nanorods and graphene could be transferred using the wet-etching method.[22] However, metal contamination [23] and the complications of the graphene and nanorods transfer processes may degrade the device performance and limit their industrial applications.

### REFERENCES

[1] A. M. Hussain, M. M. Hussain, CMOS-Technology-Enabled Flexible and Stretchable Electronics for Internet of Everything Applications, Adv. Mater. 28 (2016) 4219-4249. [2] S. Liu, L. Wang, X. Feng, Z. Wang, Q. Xu, S. Bai, Y. Qin, Z. L. Wang, Ultrasensitive 2D ZnO Piezotronic Transistor Array for High Resolution Tactile Imaging, Adv. Mater. 29 (2017) 1606346. [3] X. Wang, J. Song, J. Liu, Z. L. Wang, Direct-Current Nanogenerator Driven by Ultrasonic Waves, Science 316 (2007) 102. [4] Z. L. Wang, On Maxwell's displacement current for energy and sensors: the origin of nanogenerators, Mater. Today 20 (2017) 74-82. [5] S. Lee, S.-H. Bae, L. Lin, Y. Yang, C. Park, S.-W. Kim, et al., Super-Flexible Nanogenerator for Energy Harvesting from Gentle Wind and as an Active Deformation Sensor, Adv. Mater. 23 (2013) 2445-2449. [6] X. Wang, M. Que, M. Chen, X. Han, X. Li, C. Pan, et al., Full Dynamic-Range Pressure Sensor Matrix Based on Optical and Electrical Dual-Mode Sensing, Adv. Mater. 29, (2017) 1605817. [7] L. Zhu, L. Wang, F. Xue, L. Chen, J. Fu, X. Feng, et al., Piezo-Phototronic Effect Enhanced Flexible Solar Cells Based on n-ZnO/p-SnS Core-Shell Nanowire Array, Adv. Sci. 4 (2016) 1600185. [8] L. Zhu, L. Wang, C. Pan, L. Chen, F. Xue, B. Chen, et al., Enhancing the Efficiency of Silicon-Based Solar Cells by the Piezo-Phototronic Effect, ACS Nano 11 (2017) 1894-1900. [9] X. Li, M. Chen, R. Yu, T. Zhang, D. Song, R. Liang, et al., Enhancing Light Emission of ZnO-Nanofilm/Si-Micropillar Heterostructure Arrays by Piezo-Phototronic Effect, Adv. Mater. 27 (2015) 4447-4453. [10] Z. L. Wang, J. H. Song, Piezoelectric Nanogenerators Based on Zinc Oxide Nanowire Arrays, Science 312 (2006) 242-246. [11] X. Wang, R. Yu, W. Peng, W. Wu, S. Li, Z. L. Wang, Temperature Dependence of the Piezotronic and Piezophototronic Effects in a-axis GaN Nanobelts, Adv. Mater. 27 (2015) 8067-8074. [12] X. Wang, R. Yu, C. Jiang, W. Hu, W. Wu, Y. Ding, et al., Piezotronic Effect Modulated Heterojunction Electron Gas in AlGaN/AlN/GaN Heterostructure Microwire, Adv. Mater. 28 (2016) 7234-7242. [13] C.-T. Huang, J. Song, W.-F. Lee, Y. Ding, Z. Gao, Y. Hao, et al., GaN Nanowire Arrays for High-Output Nanogenerators, J. Am. Chem. Soc. 132 (2010) 4766-4771. [14] Y.-J. Lu, J. Kim, H.-Y. Chen, C. Wu, N. Dabidian, C. E. Sanders, et al., Plasmonic Nanolaser Using Epitaxially Grown Silver Film, Science 337 (2012) 450. [15] Y.-J. Lu, C.-Y. Wang, J. Kim, H.-Y. Chen, M.-Y. Lu, Y.-C. Chen, et al., All-Color Plasmonic Nanolasers with Ultralow Thresholds: Autotuning Mechanism for Single-Mode Lasing, Nano Lett. 14 (2014) 4381. [16] Y. B. Tang, Z. H. Chen, H. S. Song, C. S. Lee, H. T. Cong, H. M. Cheng, et al., Vertically Aligned p-Type Single-Crystalline GaN Nanorod Arrays on n-Type Si for Heterojunction Photovoltaic Cells, Nano Lett. 8 (2008) 4191-4195. [17] M. G. Kibria, S. Zhao, F. A. Chowdhury, Q. Wang, H. P. T. Nguyen, M. L. Trudeau, et al., Tuning the surface Fermi level on p-type gallium nitride nanowires for efficient overall water splitting, Nature Communications 5 (2014) 3825. [18] M. G. Kibria, F. A. Chowdhury, S. Zhao, B. AlOtaibi, M. L. Trudeau, H. Guo, et al., Visible light-driven efficient overall water splitting using p-type metal-nitride nanowire arrays, Nature Communications 6 (2015) 6797. [19] S. Fan, B. AlOtaibi, S. Y. Woo, Y. Wang, G. A. Botton, Z. Mi, High Efficiency Solar-to-Hydrogen Conversion on a Monolithically Integrated InGaN/GaN/Si Adaptive Tunnel Junction Photocathode, Nano Lett. 2015, 15, 2721-2726. [20] M. Heilmann, A. M. Munshi, G. Sarau, M. Gibelt, C. Tessarek, V. T. Fauske, et al., Vertically Oriented Growth of GaN Nanorods on Si Using Graphene as an Atomically Thin Buffer Layer, Nano Lett. 16 (2016) 3524-3532. [21] V. Kumaresan, L. Largeau, A. Madouri, F. Glas, H. Zhang, F. Oehler, et al., Epitaxy of GaN Nanowires on Graphene, Nano Lett. 16 (2016) 4895-4902. [22] C.-H. Lee, Y.-J. Kim, Y. J. Hong, S.-R. Jeon, S. Bae, B. H. Hong, et al., Flexible Inorganic Nanostructure Light-Emitting Diodes Fabricated on Graphene Films, Adv. Mater. 23 (2011) 4614-4619. [23] G. Lupina, J. Kitzmann, I. Costina, M. Lukosius, C. Wenger, A. Wolff, et al., Residual Metallic Contamination of Transferred Chemical Vapor Deposited Graphene, ACS Nano 9 (2015) 4776. [24] A. Mazid Munshi, H. Weman, Advances in semiconductor nanowire growth on graphene, Phys. Status Solidi RRL 7 (2013) 713-726. [25] M. Li, D. Liu, D. Wei, X. Song, D. Wei, A. Thye Shen Wee, Controllable Synthesis of Graphene by Plasma-Enhanced Chemical Vapor Deposition and Its Related Applications, Adv. Sci. 3 (2016) 1600003. [26] T. Detchprohm, K. Hiramatsu, K. Itoh, I. Aksaki, Relaxation Process of the Thermal Strain in the GaN/α-Al₂O₃ Heterostructure and Determination of the Intrinsic Lattice Constants of GaN Free from the Strain, Jpn. J. Appl. Phys. 31 (1992) L1454. [27] M. A. Reshchikov, H. Morkoç, Luminescence properties of defects in GaN, J. Appl. Phys. 97 (2005) 061301. [28] H.-Y. Chen, H.-W. Lin, C.-H. Shen, S. Gwo, Structure and photoluminescence properties of epitaxially oriented GaN nanorods grown on Si (111) by plasma-assisted molecular-beam epitaxy, Appl. Phys. Lett. 2006, 89, 243105. [29] Q. Li, G. T. Wang, Spatial Distribution of Defect Luminescence in GaN Nanowires, Nano Lett. 10 (2010) 1554-1558. [30] P. Huang, H. Zong, J.-J. Shi, M. Zhang, X.-H. Jiang, H.-X. Zhong, Y et al., Origin of 3.45 eV Emission Line and Yellow Luminescence Band in GaN Nanowires: Surface Microwire and Defect, ACS Nano 9 (2015) 9276-9283. [31] G. T. Hwang, H. Park, J. H. Lee, S. Oh, K. I. Park, M. Byun, et al., Self-powered cardiac pacemaker enabled by flexible single crystalline PMN-PT piezoelectric energy harvester, Adv. Mater. 26 (2014) 4880. [32] C. H. Wang, W. S. Liao, Z. H. Lin, N. J. Ku, Y. C. Li, Y. C. Chen, et al., Optimization of the Output Efficiency of GaN Nanowire Piezoelectric Nanogenerators by Tuning the Free Carrier Concentration, Adv. Energy Mater. 4 (2014) 1400392. [33] S.-J. Tsai, C.-Y. Lin, C.-L. Wang, J.-W. Chen, C.-H. Chen, C.-L. Wu, Efficient Coupling of Lateral Force in GaN Nanorod, Piezoelectric Nanogenerators by Vertically Integrated Pyramided Si Substrate, Nano Energy 37 (2017) 260-267. [34] L. Lin, C.-H. Lai, Y. Hu, Y. Zhang, X. Wang, C. Xu, et al., High output nanogenerator based on assembly of GaN nanowires, Nanotechnology 22 (2011) 475401. [35] Y. Gao, Z. L. Wang, Electrostatic Potential in a Bent Piezoelectric Nanowire. The Fundamental Theory of Nanogenerator and Nanopiezotronics, Nano Lett. 7 (2007) 2499-2505. [36] C. Y. Chen, J. H. Huang, J. Song, Y. Zhou, L. Lin, P. C. Huang, et al., Anisotropic Outputs of a Nanogenerator from Oblique-Aligned ZnO Nanowire Arrays, ACS Nano 5 (2012) 6707-6713. [37] Y. Hu, L. Lin, Y. Zhang, Z. L. Wang, Replacing a Battery by a Nanogenerator with 20 V Output, Adv. Mater. 24 (2011) 110-114. [38] G. Zhu, A. C. Wang, Y. Liu, Y. Zhou, Z. L. Wang, Functional Electrical Stimulation by Nanogenerator with 58 V Output Voltage, Nano Letters, 2012, 12 (6), 3086-309Nano Lett. 12 (2012) 3086-3090.

### SUMMARY OF THE INVENTION

In one general aspect, the present invention relates to a method for transferring nanostructures and a device having the nanostructures.

According to an embodiment of this invention, a method for transferring nanostructures comprises the steps of: forming a two-dimensional material (2D material) on a first substrate; forming a plurality of nanostructures on the 2D material; bonding a top surface of one or more of nanostructures with a head or a second substrate, and/or shaking the one or more nanostructures with or without a fluid; and separating the one or more nanostructures from the 2D material.

According to another embodiment of this invention, a device is provided with nanostructures that are formed by the above-mentioned method.

According to another embodiment of this invention, a device is provided with an array comprising one or more layers of light-emitting diodes, piezoelectric transistors, sensors (e.g. piezoelectric pressure sensors, image sensors, biosensors, or piezo-phototronic effect enhanced sensors), nanogenerators, solar cells, piezo-phototronic effect enhanced solar cells, or chemical reaction cells (e.g. photoelectrochemical water-splitting cells, piezoelectric effect enhanced photoelectrochemical water-splitting cells, or fuel cells). In this text, the term “light-emitting diode (LED)” refers to a semiconductor light source for lighting, displaying, optical sensing, and/or other applications and such devices may include: LEDs, laser diodes (LDs), micro or pixel LEDs, micro or pixel LDs, piezo-phototronic effect enhanced LEDs or LDs, or piezo-phototronic effect enhanced micro or pixel LEDs or LDs. Each of them comprises one or more nanostructures that are formed on a three-dimensional (3D) orientated morphology of a 2D material on a first substrate and then separated from the 2D material and transferred to a second substrate or a fluid or a container, wherein the orientations of the nanostructures disposed on the second substrate are random or are controlled to have one or more oblique angles.

### BRIEF DESCRIPTION OF THE DRAWINGS

FIG. 1 is a flow chart showing a method for transferring nanostructures in accordance with an embodiment of this invention.

FIG. 2A is a schematic cross-sectional diagram showing a 2D material grown on a first substrate and vertically aligned nanostructures grown on the 2D material.

FIG. 2B is a schematic cross-sectional diagram showing a 2D grown on a first substrate and obliquely aligned nanostructures grown on the 2D material.

FIG. 3 is a schematic cross-sectional diagram showing p-n junction nanostructures grown on 2D material on a first substrate in accordance with an embodiment of this invention.

FIG. 4 is a schematic cross-sectional diagram showing p-n junction nanostructures grown on 2D material on a first substrate in accordance with another embodiment of this invention.

FIG. 5 is a schematic cross-sectional diagram showing p-n junction nanostructures with DBRs grown on 2D material on a first substrate in accordance with another embodiment of this invention.

FIG. 6A is a cross-sectional view illustrating an LED array in accordance with an embodiment of this invention.

FIG. 6B is a cross-sectional view illustrating an LED array in accordance with an embodiment of this invention.

FIG. 6C is a cross-sectional view illustrating an LED array in accordance with an embodiment of this invention.

FIG. 6D is a cross-sectional view illustrating an LED array in accordance with an embodiment of this invention.

FIG. 6E is a cross-sectional view illustrating a light distribution of the LED array of FIGS. 6C and 6D.

FIG. 6F is a cross-sectional view illustrating a light distribution of the LED array of FIGS. 6C and 6D.

FIG. 6G is a cross-sectional view illustrating a light distribution of the LED array of FIGS. 6C and 6D.

FIG. 7A is a schematic diagram showing a method for transferring obliquely aligned GaN nanorods in accordance with an embodiment of this invention.

FIG. 7B is a picture showing the obliquely aligned GaN nanorods being easily separated from graphene in accordance with an embodiment of this invention.

FIGS. 8A-8J show SEM images of surface morphology of flat or three-dimensional (3D) oriented graphene nanosheets grown on a Si (100) substrate and obliquely aligned GaN nanorods (8F) and random orientated InGaN/GaN nanorods (8I) grown on the 3D oriented graphene nanosheets and upper/outer shell graphene further grown on the GaN nanorods (8J) and the 3D oriented graphene nanosheets after the GaN nanorods are separated in accordance with embodiments of this invention.

FIG. 9 shows TEM images of the obliquely aligned GaN nanorods grown on the 3D oriented nanosheets in accordance with embodiments of this invention.

FIG. 10 shows PL characterizations of produced single-crystalline GaN nanorods in accordance with an embodiment of this invention.

FIG. 11A shows pictures of a flexible nanogenerator integrated with the transferred GaN nanorods in their original, bending, and straightening states for power generation in accordance with an embodiment of this invention.

FIG. 11B is a chart illustrating the correlation between a magnified output voltage and the bending conditions of the nanogenerator shown in FIG. 11A.

FIG. 11C is a chart illustrating an output voltage and current of the nanogenerator shown in FIG. 11A.

### DETAILED DESCRIPTION OF THE PREFERRED EMBODIMENT

The detailed description of the present invention will be discussed in the following embodiments, which are not intended to limit the scope of the present invention, but can be adapted for other applications. While drawings are illustrated in details, it is appreciated that the quantity of the disclosed components may be greater or less than that disclosed, except expressly restricting the amount of the components. Wherever possible, the same or similar reference numbers are used in drawings and the description to refer to the same or like parts. It should be noted that any drawing presented are in simplified form and are not to precise scale. In reference to the disclosure herein, for purposes of convenience and clarity only, directional terms are used with respect to the accompanying drawing and should not be construed to limit the scope of the invention in any manner.

This invention discloses methods for transferring nanostructures and devices having the transferred nanostructures.

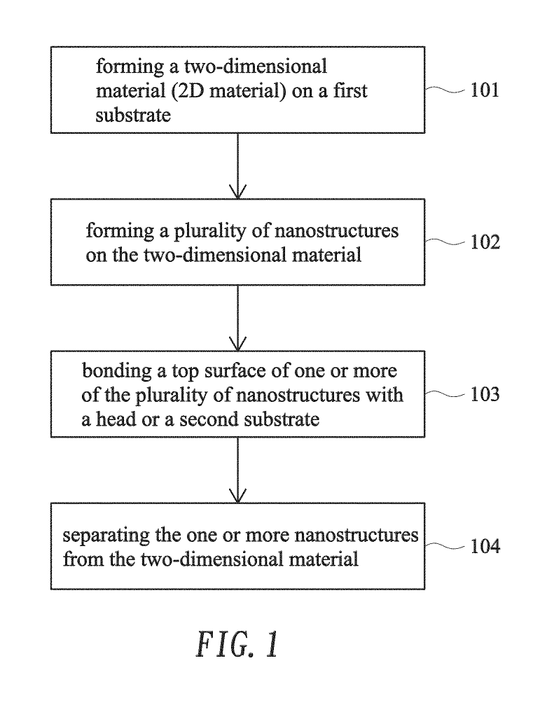

FIG. 1 is a flow chart showing a method for transferring nanostructures in accordance with an embodiment of this invention. In this text, the term “nanostructure” refers to a structure of intermediate size between microscopic and molecular structures, such as nanorods, nanowires, nanocones, nanotubes, nanodisks, nanoshells, nanoparticles, and the likes or combinations of one or more shapes of nanostructures.

Referring to FIG. 1, the method comprises the steps of: step 101, forming a 2D material on a first substrate; step 102, forming a plurality of nanostructures on the 2D material; step 103, bonding a top surface of one or more of the plurality of nanostructures with a head or a second substrate; and step 104, separating the one or more nanostructures from the 2D material.

The first substrate can be any kind of substrate such as semiconductor (e.g., silicon, SiGe, or SiC), metal (e.g., Titanium), insulator (e.g., sapphire, glass, or quartz), and combinations thereof. The 2D material is a crystalline or low-crystalline material consisting of a single or few or multi layers of atoms. The layered 2D materials feature strong in-plane covalent bonding and weak intra-plane bonding. Preferably, the 2D material comprises graphene, 2D allotropes (e.g. graphene, phosphorene, germanene, silicone, borophene), transition metal dichalcogenide (e.g., WSe₂, WS₂, or MoS₂), 2D group-IV materials, 2D group-V materials, 2D oxides, or combinations thereof. The graphene family comprises graphene, hexagonal boron nitride (hBN, white graphene), fluorographene, and graphene oxide.

Method for forming the 2D material on the first substrate and method for forming the nanostructures may include, but is not limited to, physical vapor deposition (PVD), plasma-assisted molecular beam epitaxial (PA-MBE), chemical vapor deposition (CVD), plasma enhanced chemical vapor deposition (PECVD), atomic layer deposition (ALD), Metal-organic Chemical Vapor Deposition (MOCVD), wet chemical method, or hydrothermal method.

The inventor has discovered that the grain size of the 2D material affects its morphology, and high-quality nanostructures can be achieved by using low-crystalline 2D material as a growing substrate. In addition, if the 2D material is low-crystalline, its surface morphology can be flat or 3D oriented depending on the time, surface roughness, or surface morphology of the first substrate for growing the 2D material.

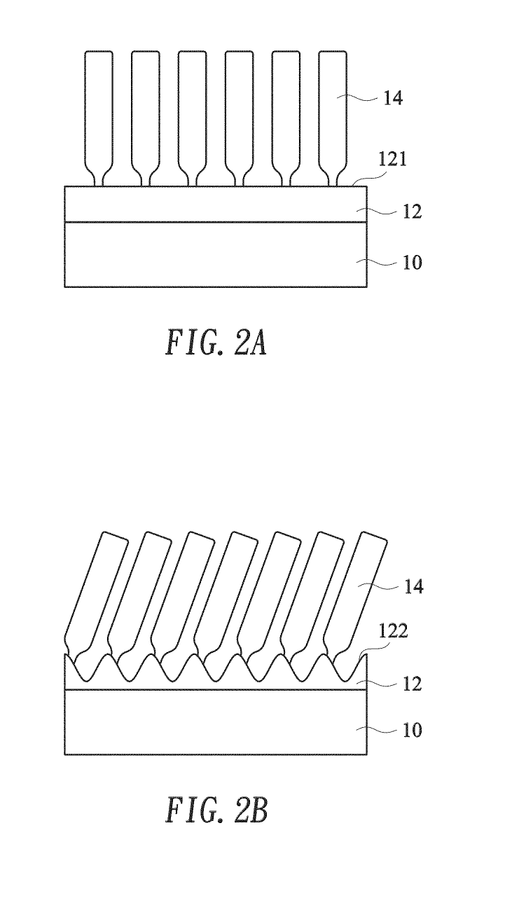

FIG. 2A is a schematic cross-sectional diagram in accordance with an embodiment of this invention. Referring to FIG. 2A, a low-crystalline 2D material 12 having a flat surface morphology 121 is grown on a first substrate 10 with a short growing period and then vertically aligned nanostructures 14 are grown on flat surface morphology 121 of the 2D material 12.

FIG. 2B is a schematic cross-sectional diagram in accordance with another embodiment of this invention. Referring to FIG. 2B, a low-crystalline 2D material 12 having a 3D oriented surface morphology 122 is grown on a first substrate 10 with a long growing period and then obliquely aligned nanostructures 14 are grown on 3D oriented surface morphology 122 of the 2D material 12. Typically the low-crystalline 2D material 12 with 3D oriented surface morphology 122 consists of few or multi layers of atoms. The low-crystalline 2D material 12 refers to a 2D material with an average small grain size, e,g., less than 500 nm. In an embodiment, the surface of the first substrate 10 is patterned or textured before or after the formation of the 2D material 12 to control the orientations and/or positions of the nanostructures.

Referring to FIGS. 2A and 2B, the grain size of the 2D material 12 and/or process parameters for growing the nanostructures 14 are controlled so that each nanostructure 14 has a bottom coupled to the 2D material 12 and the diameter of the bottom is smaller than the diameter of middle of nanostructure 14. This morphology is quite helpful for separating the nanostructures 14 from the 2D material 12. The diameter of the nanostructure 14 can be controlled by the growth substrate (e.g. the grain size or grain shape or crystallization of the 2D material, and/or surface pattern or texture morphology of the first substrate), and/or the process parameters for growing the nanostructures 14. In an embodiment, the ratio of the diameter of middle to the diameter of bottom of nanostructure 14 ranges between 2:1 and 1000:1. In an embodiment, the grain size of the 2D material 12 ranges between 3 nm and 500 nm. In an embodiment, the average grain size of the 2D material 12 is less than 500 nm. In an embodiment, the average grain size of the 2D material 12 is less than 200 nm. In an embodiment, the average grain size of the 2D material 12 is less than 100 nm. In an embodiment, the surface of the first substrate 10 is patterned or textured to control the diameter of the nanostructure 14.

Referring to FIG. 2B, it is observed that the 3D oriented surface morphology 122 are grown from the grain boundaries of the 2D material 12 with a small grain size, e,g., less than 500 nm. In one embodiment, the orientations of nanostructures 14 grown on the 3D oriented surface morphology 122 of the 2D material 12 are random with no specific direction. Referring to FIG. 2B, at least a portion of nanostructures 14 are obliquely formed on 3D oriented surface morphology 122 of the 2D material 12 by a glancing-angle epitaxy and the orientations of the portion of nanostructures 14 are controlled by processing parameters of the glancing-angle epitaxy. In an embodiment, the surface morphology of the 2D material 12 is controlled to be partially flat and partially 3D oriented, so that a portion of the nanostructures 14 formed on the 2D material 12 are vertically aligned and the other of that are obliquely aligned.

In an embodiment, the top surface of the plurality of nanostructures 14 is bonded with a head (not shown) by electrostatic force. The head is used for selectively picking up and transferring one or more nanostructures 14 from the first substrate 10 to the second substrate. The head may comprise a protruded electrode and a dielectric layer covering the protruded electrode. The head has a monopolar or bipolar electrode configuration. In addition, an electrode is formed on the top surfaces of nanostructures 14 before the transfer. The transferring procedure includes that the head contacts or approaches the electrode of one or more nanostructures to be transferred and a voltage is applied to the protruded electrode to create an electrostatic force on the one or more nanostructures. The one or more nanostructures 14 are then picked up to separate from the 2D material 12. The nanostructures 14 can be picked up and transferred individually, in groups, or as the entire array. This invention can achieve large-scale (e.g., more than or equal to centimeter-scale) in a single transfer process of nanostructures 14. In particular, this invention can achieve extra large-scale (e.g., more than or equal to meter-scale) in a single transfer process of nanostructures 14 by placing multi-wafers of nanostructures 14 side by side, and then separate the whole nanostructures 14 from the multi-wafers at a time. The one or more nanostructures 14 are then released onto a second substrate or transferred into a fluid (e.g. gas, water or viscous solution) or a container with the fluid for production of a device (e.g. chemical reaction cells).

In an embodiment, a bonding layer is utilized during the formation and/or transfer of the nanostructures 14 to the second substrate. The bonding layer may be made of metals, solders, thermoplastic polymers, or combinations thereof. If necessary, the bonding layer can be electrically conductive. In an embodiment, the top surfaces of one or more nanostructures 14 are bonded to the bonding layer of head or second substrate under heat and/or pressure, and then the one or more nanostructures 14 are lifted to separate from the 2D material. The bonding layer may be a permanent layer or an intermediate layer and may undergo a phase change (e.g., solid to liquid or liquid to solid) during the formation of device or transfer of nanostructures 14. The bonding layer may be patterned before the transfer. In an embodiment, the one or more nanostructures 14 are then released into a fluid (e.g. gas, liquid, or viscous solution) for production of a device (e.g. a chemical reaction cell).

In an embodiment, an adhesive layer is utilized during the formation and/or transfer of the nanostructure to the second substrate. A head or a second substrate includes an adhesive layer, which is made of suitable materials such as adhesive polymers. In an embodiment, the top surfaces of one or more nanostructures 14 are bonded to the adhesive layer of head or second substrate under heat and/or pressure, and then the one or more nanostructures 14 are lifted to separate from the 2D material. The adhesive layer may be a permanent layer or an intermediate layer removed after the transfer. The adhesive layer may be patterned before the transfer. In an embodiment, the one or more nanostructures 14 are then released into a fluid (e.g. gas, water, or viscous solution). While embodiments of the present invention are described with specific regard to separating the nanostructures by bonding, adhering or electrostatic attraction, it is to be appreciated that embodiments of the invention are not so limited and that certain embodiments may also be applicable to other separating means. Alternatively, a shaking procedure is used to separate the nanostructures 14 from the 2D material 12 in some embodiments. In an embodiment, the shaking procedure is performed and combined with the above-mentioned bonding, adhering, or electrostatic attraction method. In an embodiment, the shaking procedure comprises purging a fluid, such as a gas (e.g., air, N₂, Ar) or a liquid (e.g., water, or solution), to the nanostructures 14, so that the nanostructures 14 are separated from the 2D material 12. In an embodiment, the shaking procedure comprises creating a partial vacuum (e.g., by a vacuum pump) with a gas flow to suck the nanostructures 14 and then the nanostructures 14 are separated from the 2D material 12. In an embodiment, the shaking procedure comprises vibrating and/or pulling the nanostructures 14 by a device, such as a vibrator or a robot.

In an embodiment, an additional adhesive layer (e.g. polymethylmethacrylate (PMMA)) may be spin-coated on the nanostructures 14 and the 2D material 12 (FIG. 81) to avoid earlier separation before the transfer.

In an embodiment, the flat surface morphology 121 and/or 3D surface morphology 122 of 2D material 12 formed on the first substrate 10 can be repeatedly used for growing another batch of nanostructures 14 after cleaning. This feature can save a lot of material cost, process cost, and time. In an embodiment, a portion, typically less than 50%, of the bottom area of one or more nanostructures 14 has the residue of 2D material coupled to the nanostructures 14 after the separating. The residue can be easily removed by a clean procedure if necessary.

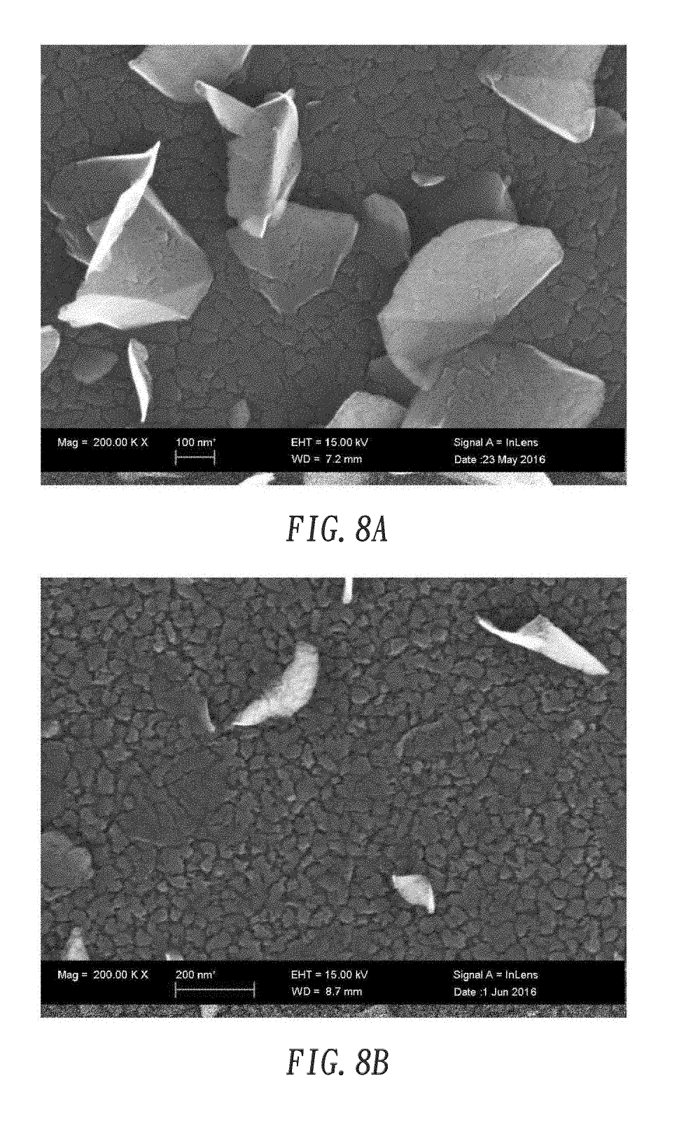

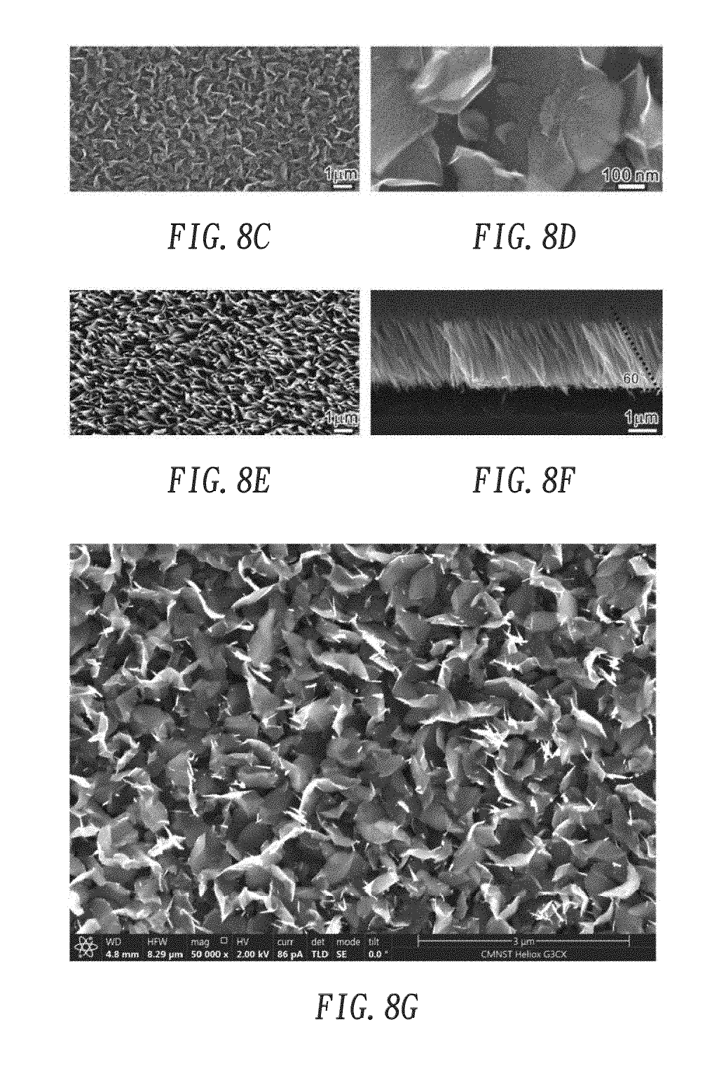

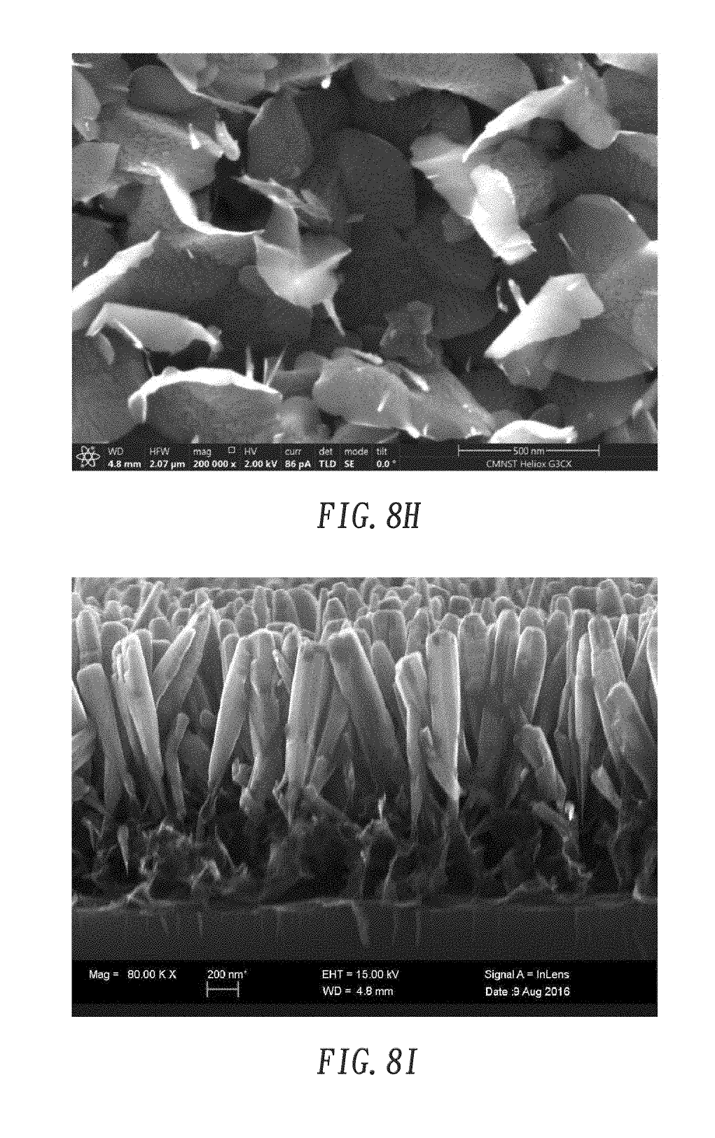

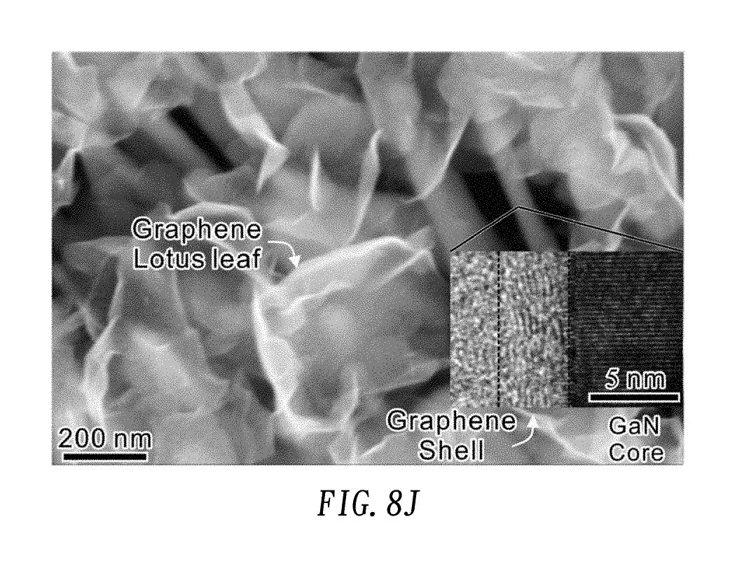

In an embodiment, the transferred one or more nanostructures 14 are used to produce one or more layers of devices, e.g., light-emitting diodes, piezoelectric transistors, sensors (e.g. piezoelectric pressure sensors, image sensors, biosensors, or piezo-phototronic effect enhanced sensors), nanogenerators, solar cells, piezo-phototronic effect enhanced solar cells, or chemical reaction cells (e.g. photoelectrochemical water-splitting cells, piezoelectric effect enhanced photoelectrochemical water-splitting cells, or fuel cells). In this text, the term “a light-emitting diode (LED)” refers to a semiconductor device for lighting, displaying, optical sensing, and/or other applications and, and such devices may include, but are not limited to: LEDs, laser diodes (LDs), micro or pixel LEDs, micro or pixel LDs, piezo-phototronic effect enhanced LEDs or LDs, or piezo-phototronic effect enhanced micro or pixel LEDs or LDs. The device can be flexible by transferring the nanostructures 14 to a flexible substrate. In an embodiment, the second substrate is a permanent substrate, i.e., a component of the device. In an embodiment, the transferred one or more nanostructures 14 are used to produce an array of one or more semiconductor devices such as light emitting diodes (LEDs) comprising semiconductor or 2D material layers or p-n diodes or p-i-n diodes or being designed to perform a predetermined electronic function (e.g. flexible diode, transistor, pressure sensor, or integrated circuit) or photonic function (e.g., flexible micro-LED, photodetector, or micro-laser). In an embodiment, each nanostructure may include one or more semiconductor (e.g., silicon) or 2D material layers with controlled dopant concentrations. In this text, the term “array” refers to one or more objects arranged in order or in a particular way. In an embodiment, the p-n diodes or p-i-n diodes may include a compound semiconductor having a bandgap corresponding to a specific region in the spectrum. For example, each p-n diode or p-i-n diode may include one or more layers based on 2D material (e.g. BN, graphene, MoS₂, WS₂, or WSe₂) or II-VI materials (e.g. ZnSe) or III-V nitride materials (e.g. GaN, AlN, InN), and ternary (e.g. indium gallium arsenide (InGaAs)) and quaternary (e.g. aluminium gallium indium phosphide (AlInGaP)) and other possible alloys of the foregoing materials. In this text, the term “III-V” refers to a substance composed of two or more elements selected from groups III and V, the term “II-VI” refers to a substance composed of two or more elements selected from groups II and VI, and so forth. In an embodiment, an upper and/or outer shell made of 2D material can be further formed on top and/or sidewalls of the nanostructures, and the morphology of 2D material may be single atomic layer or multi atomic layer of disk or shell (FIG. 8J). In an embodiment, metallic or semiconductor nanoparticles (NPs) can be coated on the nanostructures (e.g. Platinum (Pt) NPs or graphene oxide quantum dots as catalysts for chemical reaction (e.g. photoelectrochemical water splitting or so called photoelectrochemical hydrogen production). In an embodiment, catalyst nanoparticles, e.g., Rh/Cr₂O₃ core/shell NPs, may be coated on nanostructures for chemical reaction (e.g. photochemical water splitting), and the coating process can be performed before or after separating nanostructures from the 2D material. In some embodiments, methods (e.g., FIGS. 1-3) described in this invention are used to generate a three-dimensional integrated circuit (3D IC), which is an integrated circuit by stacking same or different the above-mentioned devices and interconnecting them vertically so that they behave as a single device. In an embodiment, the transferred one or more nanostructures 14 are used to fabricate a first device or a first device array, and one or more steps of FIG. 1 are repeated to generate or separate more (same or different) nanostructures, which are used to fabricate one or more devices or device arrays stacked on the first device or the first device array.

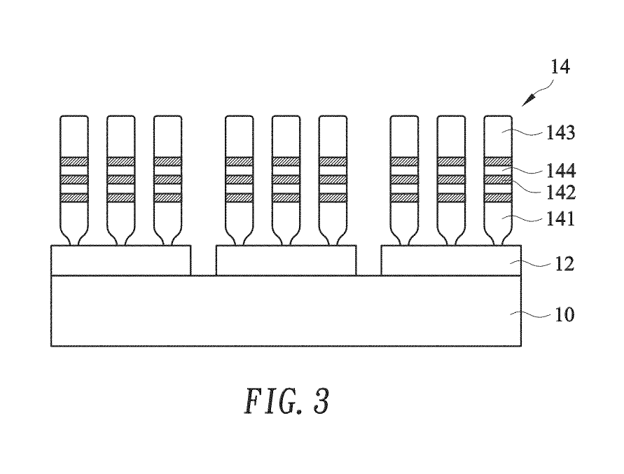

FIG. 3 is a schematic diagram illustrating that one or more nanostructures are used to produce a light-emitting diode or a laser diode in accordance with an embodiment of this invention. Referring to FIG. 3, each nanostructure 14 comprises an n-type III-V (e.g., GaN, InGaN, AlGaN)) or II-VI (e.g. ZnSe, CdTe, CdZnSe, or ZnO) nanorod 141, one or more III-V (e.g., indium gallium nitride (InGaN)) and/or II-VI and/or 2D material (e.g. BN, graphene, or MoS₂) nanodisks 142 disposed on the n-type III-V or II-VI nanorods 141, and a p-type III-V or II-VI nanorod 143 disposed on top of the one or more III-V and/or II-VI and/or 2D material nanodisks 142. If the number of one or more III-V and/or II-VI and/or 2D material nanodisks 142 is equal to or greater than two, an III-V (e.g., GaN) or II-VI or 2D material barrier 144 may be interposed between each two of the III-V and/or II-VI and/or 2D material nanodisks 142. In addition, an electrode (not shown), metal/dielectric layer coating (for nanorod lasing), and/or other functional layers (e.g. 2D materials) may be formed on the p-type III-V or II-VI or 2D material nanorods 143 before the transfer. In another embodiment, III-V or II-VI nanorod 141 is p-type, and III-V or II-VI nanorod 143 is n-type.

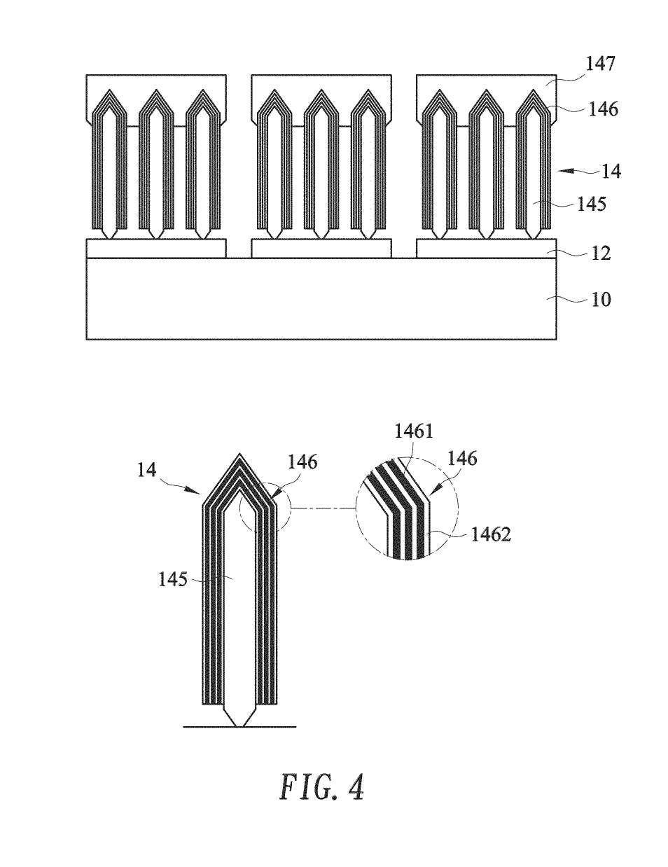

FIG. 4 is a schematic diagram illustrating that one or more nanostructures 14 are used to produce a light-emitting diode in accordance with another embodiment of this invention. Referring to FIG. 4, each nanostructure 14 comprises an n-type III-V (e.g., GaN) or II-VI (e.g., ZnO) or 2D material (e.g. MoS₂) core 145 surrounded by multiple quantum well (MQW) sheath 146 and a p-type III-V (e.g., GaN) or II-VI (e.g., ZnO) or 2D material (e.g. MoS₂) outer shell 147 on the MQW sheath 146. The multiple quantum well (MQW) sheath 146 consists of two or more III-V (e.g, InₓGa₁₋ₓN) and/or II-VI and/or 2D material (e.g. MoS₂) layers 1461 and an III-V (e.g., GaN) or II-VI (e.g., ZnO) or 2D material (e.g. BN) barrier layer 1462 interposed between each two of the III-V (e.g., InₓGa₁₋ₓN) and/or II-VI (e.g., ZnO) and/or 2D material (e.g. MoS₂) layers 1461. The nanostructures 14 can be grown by MOCVD technique. In addition, an electrode (not shown), metal/dielectric layer coating (for nanorod lasing), and/or other functional layers (such as 2D materials) may be formed on the p-type III-V or II-VI nanorods 147 or other portions of nanorods 14 before the transfer. In another embodiment, III-V or II-VI core 145 is p-type, and III-V or II-VI or 2D material outer shell 147 is n-type.

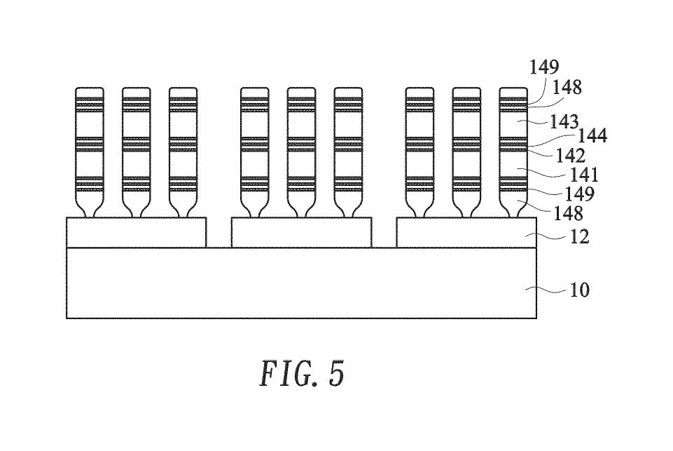

FIG. 5 is a schematic diagram illustrating that one or more nanostructures are used to produce a laser diode in accordance with an embodiment of this invention. Referring to FIG. 5, each nanostructure 14 comprises a first layer (not shown) of III-V or II-VI nanorod, a lower distributed Bragg reflectors (DBRs) consisting of alternating III-V (e.g., GaN/AlN) and/or II-VI and/or 2D material (e.g. MoS₂) (148/149) nanodisks (or nanoshells) disposed on the first layer, an n-type III-V (e.g., gallium nitride) or II-VI nanorod 141 (or nanodisk/nanoshell) disposed on the lower distributed Bragg reflectors (148/149), one or more III-V (e.g., indium gallium nitride (InGaN)) and/or II-VI and/or 2D material (e.g. MoS₂) nanodisks 142 disposed on the n-type III-V or II-VI nanorod, a p-type III-V (e.g., GaN) or II-VI (e.g., ZnSe or ZnO) nanorod 143 disposed on top of the one or more III-V and/or II-VI and/or 2D material (e.g. MoS₂) nanodisks 142, and an upper distributed Bragg reflectors (DBRs) consisting of alternating III-V (e.g., GaN/AlN) and/or II-VI (e.g., ZnO) and/or 2D material (148/149) nanodisks disposed on the p-type III-V or II-VI nanorod 143. If the number of one or more III-V and/or II-VI and/or 2D material (e.g. MoS₂) nanodisks 142 is equal to or greater than two, an III-V (e.g., GaN) or II-VI or 2D material (e.g. BN) barrier 144 is interposed between each two of the III-V and/or II-VI and/or 2D material (e.g. MoS₂) nanodisks 142. In addition, an electrode (not shown), metal/dielectric layer coating (for nanorod lasing), and/or other functional layers (such as 2D materials) may be formed on the upper distributed Bragg reflectors (DBRs) or formed on other portions of nanostructures 14 before the transfer. In another embodiment, III-V or II-VI nanorod 141 is p-type, and III-V or II-VI nanorod 143 is n-type.

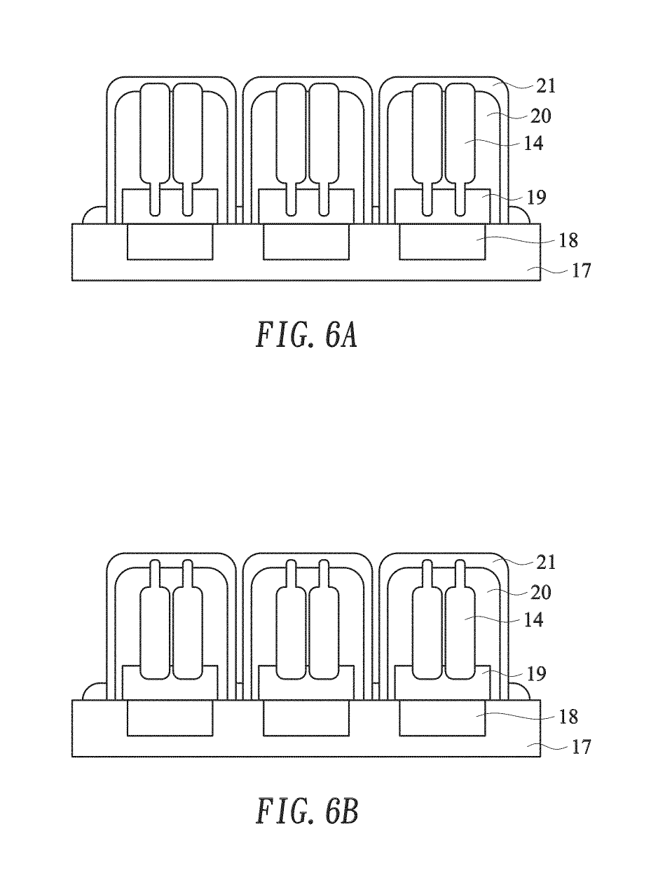

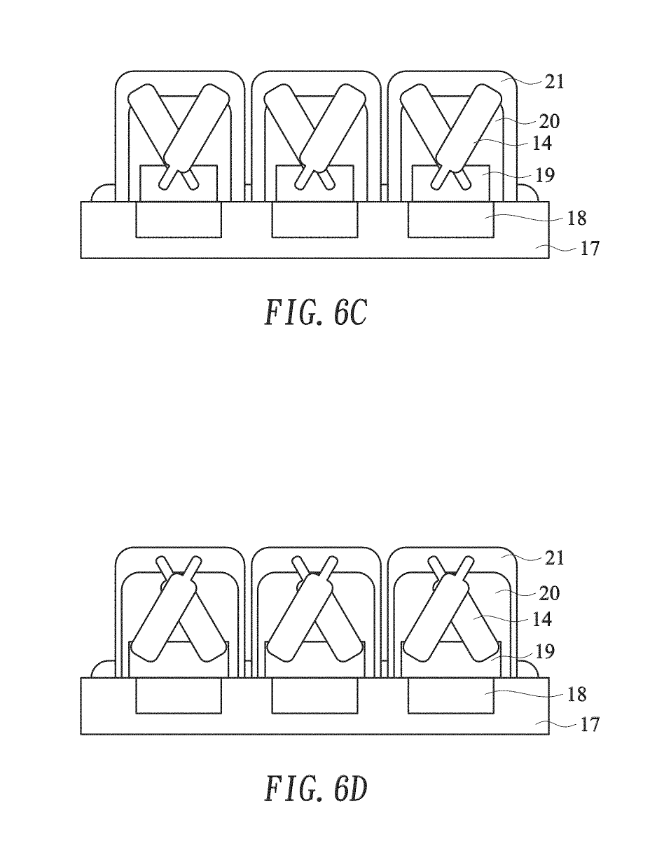

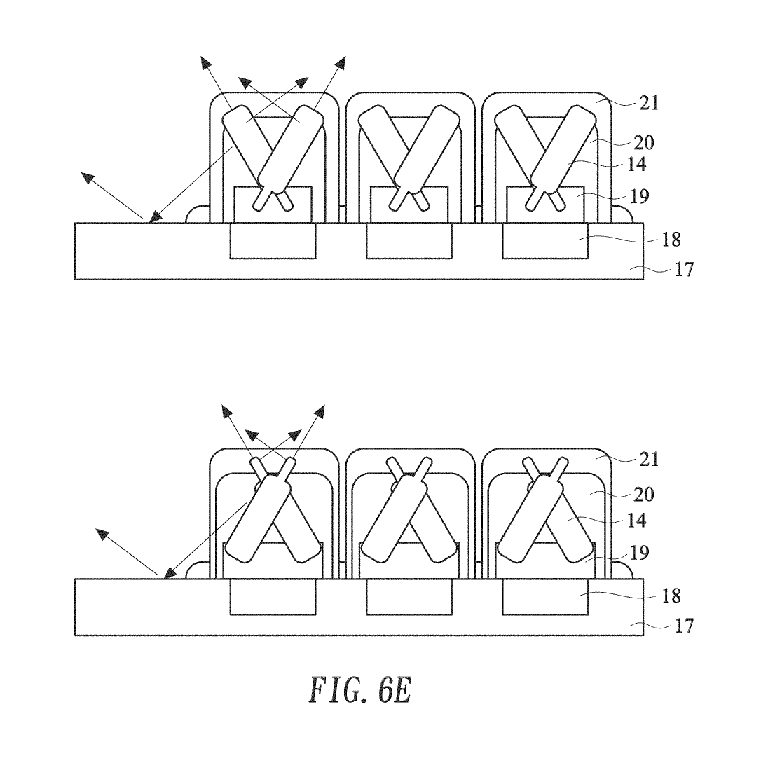

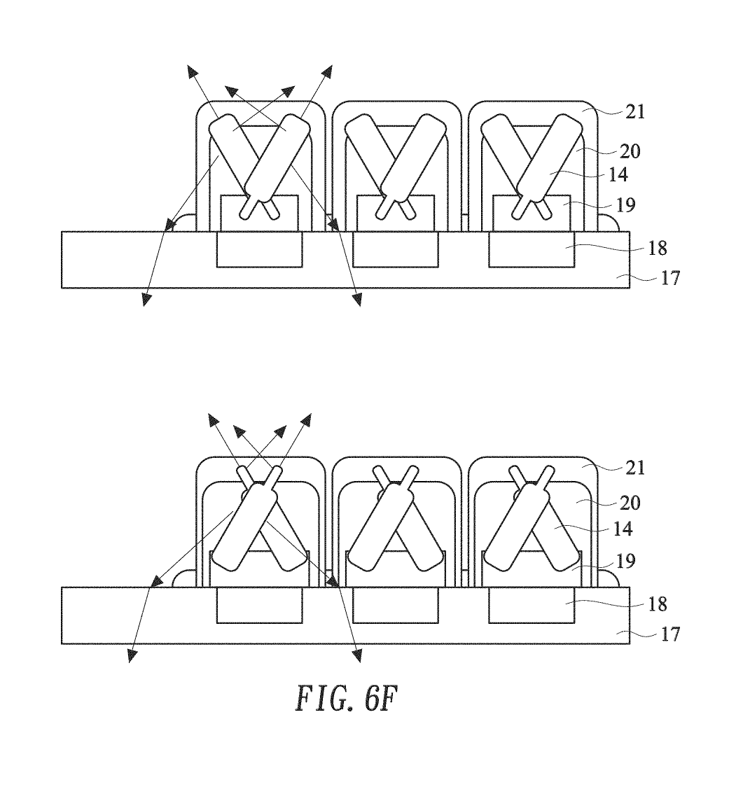

FIG. 6A is a cross-sectional view illustrating an LED array in accordance with an embodiment of this invention. While some embodiments are described with specific regard to LED array, it is to be appreciated that embodiments of the invention are not so limited and that certain embodiments may also be applicable to other type of components. Referring to FIG. 6A, nanostructures 14 are formed on a 2D material and separated from the 2D material using the method shown in FIG. 1. Nanostructures 14 may comprise p-i-n diodes or p-n diode as shown in FIG. 3 or FIG. 4 or FIG. 5 or comprise one or more semiconductors (e.g., silicon, III-V, II-VI) or single or multi atomic layers of 2D material (e.g. MoS₂) layers with controlled dopant concentrations or comprise a configuration designed to perform a predetermined electronic function or photonic function. Driver contacts 18 are formed on a flexible substrate 17, which may be, but is not limited to, a display substrate or a lighting substrate. A first electrode layer 19 may be formed on each of the driver contact 18. Optionally a barrier layer (not shown) may be further included in the first electrode layer 19, which may be made of a high work-function metal such as Ni, Au, Ag, Pd, and Pt or a low work-functional metal such as Al or In, depending on the polarity (n-type or p-type) of contacted portion of the nanostructure 14. In an embodiment, the first electrode layer 19 may be reflective to light emission. In another embodiment, the first electrode layer 19 may also be transparent to light emission. Transparency may be accomplished by making the electrode layer very thin or using transparent electrodes (such as indium tin oxide) to minimize light absorption. Barrier layer may be made of, but is not limited to, Pd, Pt, Ni, Ta, Ti and TiW. Barrier layer may prevent the diffusion of components into the p-n diode or p-i-n diode. As previously described, a head or a second substrate is used to bond the top surfaces of nanostructures 14 formed on the 2D material, and then the nanostructures 14 are separated from the 2D material. The head or the second substrate may release the separated nanostructures 14 to the flexible substrate 17 with each nanostructure 14 being placed over a driver contact 18. A dielectric layer 20, such as silicon nitride or silicon oxide layer, may then be formed to surround each of the nanostructure 14 but expose the top surface of the nanostructure 14. A second electrode layer 21 may then be formed over the dielectric layer 20 and contact with the top surface of each nanostructure 14. The second electrode layer 21 may be made of a high work-function metal a low work-functional metal depending on the polarity of contacted portion of the nanostructure 14. In an embodiment, the second electrode layer 21 may be a common contact line formed over a series of red-emitting (R), green-emitting (G) or blue-emitting (B) micro LEDs or formed over all micro LEDs within a pixel. In an embodiment, the second electrode layer 21 may be reflective to light emission. In another embodiment, the second electrode layer 21 may also be transparent to light emission.

FIG. 6B is a cross-sectional view illustrating an LED array in accordance with an embodiment of this invention. Referring to FIG. 6B, nanostructures 14 are formed on a 2D material using the method shown in FIG. 1. Nanostructures 14 may comprise p-i-n diodes or p-n diode as shown in FIG. 3 or FIG. 4 or FIG. 5 or comprise one or more semiconductor (e.g., silicon, III-V, II-VI) single or multi atomic layers of 2D material (e.g. MoS₂) layers with controlled dopant concentrations or comprise a configuration designed to perform a predetermined electronic function or photonic function. Driver contacts 18 are formed on a flexible substrate 17, which may be, but is not limited to, a display substrate or a lighting substrate. A first electrode layer 19 may be formed on each of the driver contact 18. The first electrode layer 19 is then used a bonding layer to bond the top surfaces of nanostructures 14 formed on the 2D material, and then the nanostructures 14 are separated from the 2D material. A dielectric layer 20, such as silicon nitride or silicon oxide layers, may then be formed to surround each of the nanostructure 14 but expose the top surface of the nanostructure 14. A second electrode layer 21 may then be formed over the dielectric layer 20 and contact with the top surface of each nanostructure 14. In an embodiment, the second electrode layer 21 may be a common contact line formed over a series of red-emitting (R), green-emitting (G) or blue-emitting (B) micro LEDs.

FIG. 6C is a cross-sectional view illustrating an LED array in accordance with an embodiment of this invention. The LED array of this embodiment has configuration similar to that of FIG. 6A. The difference between them is that the nanostructures 14 are obliquely formed on the 2D material instead of being vertically aligned.

FIG. 6D is a cross-sectional view illustrating an LED array in accordance with an embodiment of this invention. The LED array of this embodiment has configuration similar to that of FIG. 6B. The difference between them is that the nanostructures 14 are obliquely formed on the 2D material instead of being vertically aligned. In addition, a sidewall reflector (not shown) may be formed between two individual diodes having different defined pixel or array color to avoid optical cross talk from each other. The sidewall reflector may consist of metal core/dielectric shell.

FIG. 6E is a cross-sectional view illustrating a light distribution of the LED array of FIGS. 6C and 6D. Referring to FIG. 6E, lights emitted from the oblique nanostructures 14 can be random with no specific direction, and the surface of the flexible substrate 17 may be coated or deposited a reflector to reflect light emitted from the nanostructures 14.

FIG. 6F is a cross-sectional view illustrating a light distribution of the LED array of FIGS. 6C and 6D. Referring to FIG. 6F, lights emitted from the oblique nanostructures 14 can be random with no specific direction, and are transmitted through the (transparent) flexible substrate 17.

FIG. 6G is a cross-sectional view illustrating a light distribution of the LED array of FIGS. 6C and 6D. Referring to FIG. 6G, lights emitted from the oblique nanostructures 14 can be random with no specific direction, and the second electrode layer 21 or the surface of the second electrode layer 21 reflects the lights through the flexible substrate 17.

Referring to FIGS. 6E, 6F, and 6G, the LED array with obliquely aligned nanostructures 14 (e.g., p-n or p-i-n diodes) could produce good results or effects. For example, if the LED array is used as a light source, it can emit light with uniform light distribution. Inorganic LEDs or LDs are inherently directional with regards to their distribution and this is amplified when the packaging of these devices includes reflector cups. These devices produce spotlight type distributions that are not always suitable for the final product, and probably results in the end user observing a non-uniform light distribution (bright spots and streaks) caused by the bright on-axis light. Manufacturers avoided these issues by adding heavy diffuser plates to limit bright spotlighting and adding strips of LEDs pointed in multiple directions and locations that require illumination. There have been significant challenges in distributing the light efficiently where desired. In contrast, lights emitted from the nanostructures 14 of this invention can be random with no specific direction, and therefore a uniform light distribution can be achieved. This feature allows manufacturers produce light sources with uniform and efficient lighting distributions and thermal management without using expensive and complicated light guides and diffusers, which requires a large heat sink to avoid the device degradation due to overheat.

Referring to FIGS. 6A-6G, in one embodiment the nanostructures 14 are preferably transferred to a flexible substrate 17 for construction of piezoelectric devices in formats that are thin, flexible and, in some cases, mechanically stretchable. The piezoelectric devices may include, but is not limited to, piezoelectric transistors, piezoelectric pressure sensors, nanogenerators, or piezo-phototronic effect enhanced sensors, solar cells, LEDs, or water-splitting cells. The experimental results show that the produced flexible piezoelectric devices with performance characteristics that can match and even are superior to those of conventional, rigid devices.

In a particular embodiment of this invention, an efficient approach is demonstrated to directly transfer obliquely aligned single-crystalline GaN nanorods without process damage using three-dimensional (3D) oriented graphene nanosheets grown on Si (100) substrates. The transfer technique can be easily integrated with the fabrication of a transparent, flexible vertically integrated nanogenerator (VING) with high performance. The nanocrystalline surface of the 3D oriented nanosheets reduces the contact force at the GaN nanorod/graphene interface for the direct transfer, while the 3D oriented surface morphology leads to the oblique nanorod alignment. The flexible VING using the transferred GaN nanorods converted mechanical deformation into electric energy with a high output voltage of up to 8 V and output current of 1.2 μA. This example indicates that nanocrystalline graphene or other sp²-bonded two-dimensional (2D) materials could be applicable to grow and transfer single-crystalline III-V and II-VI nanorod arrays,[24] providing a new path to integrate entire layers of nanostructures in arbitrary systems for a wide range of applications.

The methods, measurements, and results of the particular embodiment are disclosed as follows.

The wafer-scale 3D oriented graphene nanosheets were grown on Si (100) wafers using a remote radio frequency (13.56 MHz) plasma-enhanced chemical vapor deposition (remote PECVD) system. A clean Si substrate was placed in the center of a quartz tube mounted inside the remote PECVD system. The 3D oriented graphene nanosheets were grown without any catalysts or intermediates layer at 400-700° C. with CH₄ (100 mTorr) plasma for 1 hr. The GaN nanorods were grown on the 3D oriented graphene nanosheets without any catalysts by an ultrahigh-vacuum radio-frequency plasma-assisted molecular beam epitaxial (UHV PA-MBE) system under a nitrogen-rich environment with a high substrate temperature fixed at 600-850° C. The obliquely aligned GaN nanorods were obtained by glancing-angle epitaxy with the incident molecular beam subtended an angle of approximately 60° relative to the textured graphene surface at a relatively low growth temperature (600-850° C.). Consequently, Ga adatoms were less mobile, and adsorbed on the sites as they landed, resulting in the oblique alignment. The strain of the nanogenerators can be adjusted by placing different lengths of objects in between the walls to control the wall distances.

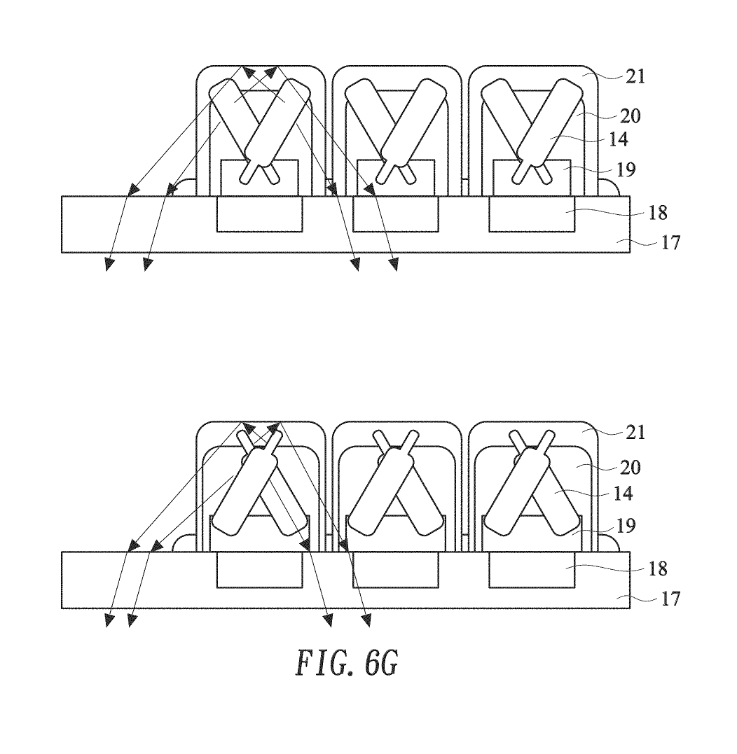

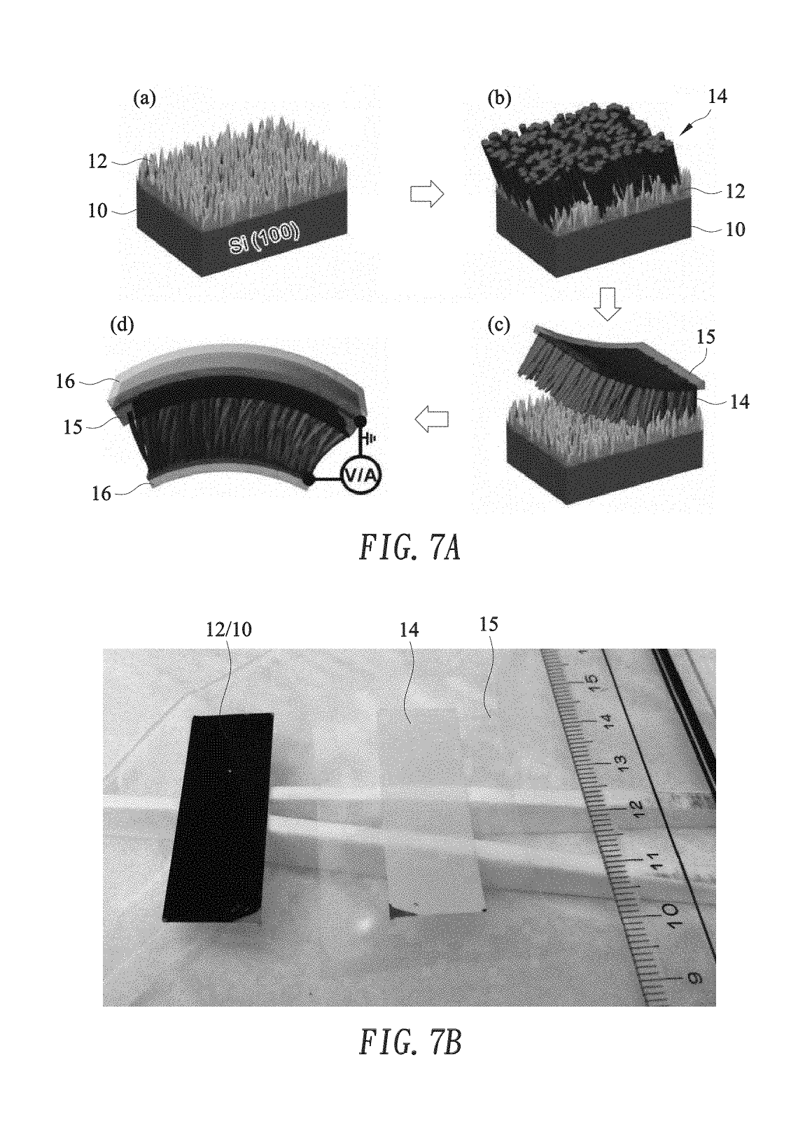

FIG. 7A is a schematic diagram showing the growth and transfer method for obliquely aligned GaN nanorods in accordance with an embodiment of this invention. The method consists of the following steps: step (a) growth of the 3D oriented graphene nanosheets 12 on a Si (100) substrate 10; step (b) epitaxy of obliquely aligned single-crystalline GaN nanorods 14 on the 3D oriented nanosheets 12; and step (c) release of the entire GaN nanorod array from the 3D oriented graphene nanosheets 12 using a tape 15 supported on a polyethylene terephthalate (PET) substrate. In addition, to fabricate a flexible electronic device, the GaN nanorods 14 were transferred onto the transparent flexible ITO-coated PET substrates 16, as shown in step (d). The tape 15 was composed of three layers, a PET thin film sandwiched between two adhesive PMMA layers with a total thickness of approximately 5 μm, which also acted as an insulating layer for the capacitor-type VING devices in this example. FIG. 7B is a picture showing the obliquely aligned GaN nanorods 14 being easily separated from graphene 12 by tape 15 in accordance with an embodiment of this invention. Referring to FIG. 7B, the GaN nanorods array 14 with a centimeter length scale (4 cm×1.5 cm) can be entirely transferred at a time. According to the method of this invention, the conventional process of spin coating PMMA as a supporting medium onto the nanorods for transfer by wet etching was avoided.[22] The 3D oriented graphene nanosheets with a variety of morphologies, such as petal-, turnstile-, maze-, and cauliflower-like shapes, have been grown, and the morphology is dependent on the type of plasma source and a series of growth parameters, such as the gas type, gas composition, and gas concentrations, chamber pressure, growth temperature, and plasma power.[25] FIG. 8A and FIG. 8B are SEM images showing the grown of graphene is controlled so that a portion of its surface morphology is flat and the other portion is 3D oriented. FIG. 8C is a SEM image showing the petal-like morphology of the 3D oriented graphene nanosheets used in FIG. 7A. FIG. 8D is a high-magnification SEM image showing that the graphene was nanocrystalline with a grain size ˜30 nm, and the nucleation of the 3D oriented graphene nanosheets initiated at the grain boundaries of the nanocrystalline graphene. Next, high-quality obliquely aligned GaN nanorods were epitaxially grown on the 3D oriented graphene nanosheets without catalysts or intermediate layers using PA-MBE. The top-view and cross-sectional SEM images of the GaN nanorods are shown in FIG. 8E and FIG. 8F, respectively, and show approximately 2 μm-long GaN Nanorods with an approximately 60° oblique angle. FIGS. 8G and 8H are SEM images showing the 3D oriented graphene nanosheets after the GaN nanorods are separated. FIG. 8I is a SEM image showing GaN nanocones grown on the 3D oriented graphene nanosheets. FIG. 8J is a SEM image showing lotus-like graphene nanoleafs and graphene nanoshells are further grown on top surfaces and sidewalls of the GaN nanorods that are grown on the 3D oriented graphene nanosheets.

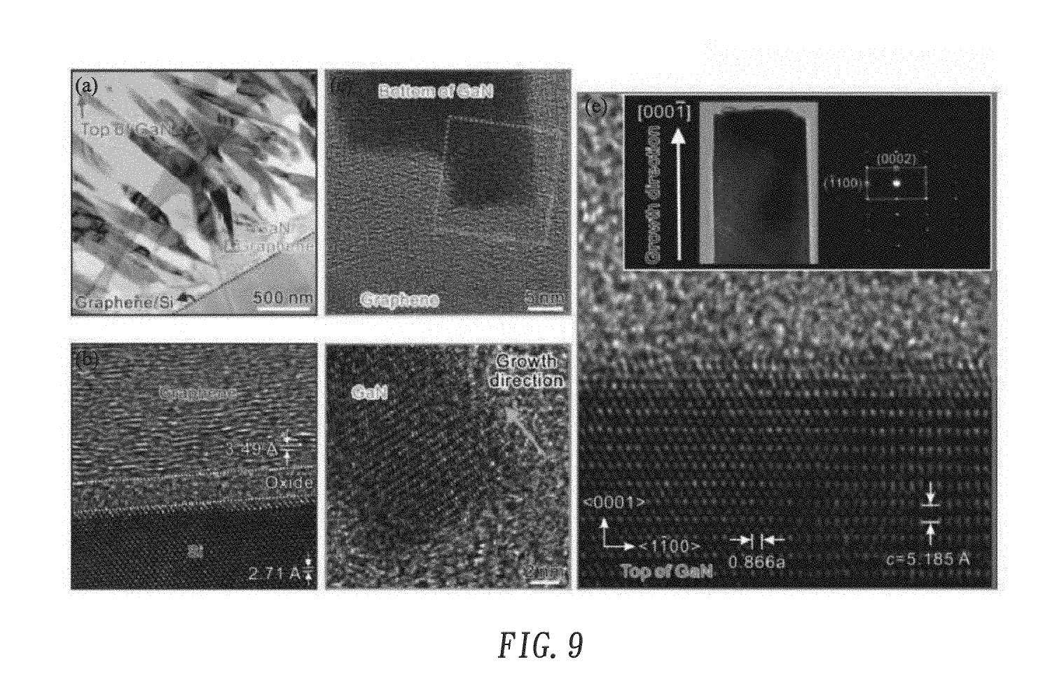

The structure of the obliquely c-axis aligned GaN Nanorods grown on the 3D oriented graphene nanosheets was analyzed in detail using transmission electron microscopy (TEM). The low-magnification cross-sectional TEM image of the ˜2-μm-long GaN Nanorods grown on 3D oriented graphene nanosheets is shown in FIG. 9(a). The high-resolution TEM (HR-TEM) image taken at the interface between the graphene and the Si (100) substrate (FIG. 9(b)) shows the structure of the multilayer graphene with a lattice constant (d) of ˜3.49 Å. A thin layer of native oxide (˜2.2 nm) was observed on the Si substrate, indicating that crystalline alignment was not required to grow the 3D oriented graphene nanosheets; thus, the 3D oriented graphene nanosheets can be grown on any substrates of choice that sustain the process temperatures. The grain size and grain shape of the graphene surface could affect the morphology of the GaN nanorods. Indeed, the higher magnification TEM images (FIG. 9(c) and FIG. 9(d)) show that the diameter (D) of the GaN Nanorods at the GaN/graphene interface was relatively smaller, approximately 10 nm, than that of the Nanorods grown on transferred graphene with the grain sizes larger than 500 nm (D=˜40 nm by PA-MBE [21] and ˜150 nm by metal-organic vapor phase epitaxy (MOVPE) [20]). The radial growth was prominent along the axial direction (FIG. 9(c)), and the diameter reached a maximal value of ˜150 nm at approximately 1 μm away from the bottom. As the nanorods were grown longer than 1 μm in length, they reached a self-equilibrated state; thus, the diameter remained constant, approximately 50 nm at the top. In contrast to the double truncated conical GaN nanorods grown on the 3D oriented graphene nanosheets, the diameters of nanorods are uniform along the entire nanorods grown on the highly crystalline transferred graphene (D=40 nm and the length was 500 nm by PA-MBE [21], and D=150 nm and the length was 2 μm by MOVPE [20]). Thus, the much smaller diameter at the bottom of the GaN nanorods was influenced by the smaller grain size of the 3D oriented graphene nanosheets for self-organized epitaxial growth. The surface area ratio between the top (D=˜50 nm) and bottom (D=˜10 nm) diameters of the GaN nanorods grown on 3D graphene nanosheets was 25-fold higher than that of the nanorods grown on the highly crystalline transferred graphene; thus, the separation of the entire array of GaN nanorods can be easily achieved by using only handling tape. The selected-area electron diffraction (SAED) patterns shown in the inset of FIG. 9(e) confirmed that the GaN nanorods were single crystals with growth along the c-axis direction. The lattice constant (c) (˜5.185 Å) and c/a ratio (˜1.626) of the GaN nanorods (FIG. 9(e)) were identical to the intrinsic lattice constants of wurtzite GaN, [26] indicating that the GaN nanorods grown on the nanocrystalline graphene surface were nearly strain-free single crystals.

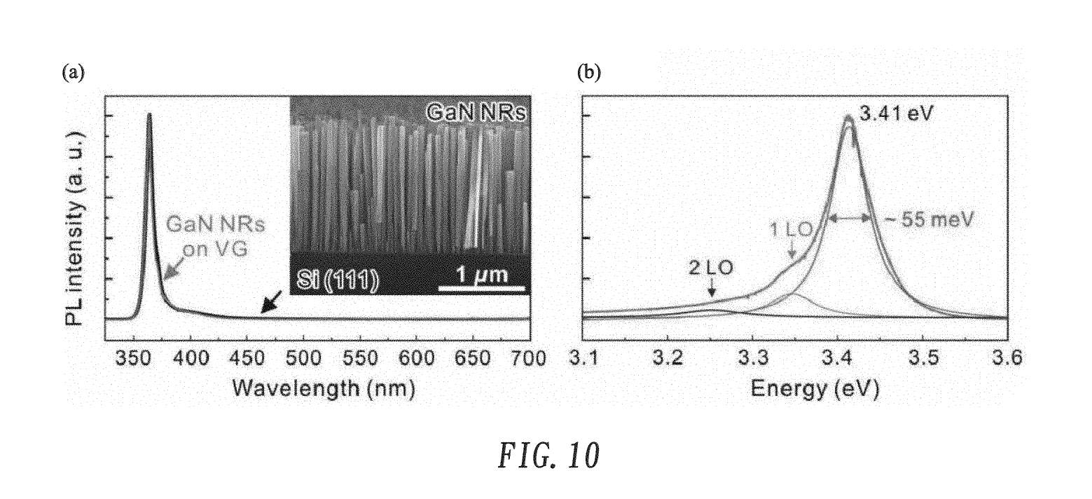

The crystal quality and optical properties of the grown GaN nanorods were characterized using room temperature photoluminescence (RT-PL) using a spectrometer with a 325 nm excitation light source from a He—Cd laser. The PL spectra in FIG. 10(a) are almost identical for the GaN nanorods grown on the 3D oriented graphene nanosheets (blue curve) and on the single-crystalline Si (111) substrate (black curve); the cross sectional SEM image is shown in the inset of FIG. 10(a). Similar to the PL for the vertical GaN nanorods grown on Si (111), the PL spectrum for the oblique GaN nanorods grown on the 3D oriented graphene nanosheets exhibited a strong near-band-edge (NBE) emission at 363 nm (3.41 eV) with a full width at half maximum (FWHM) of 55 meV (FIG. 10(b)). In addition to the 3.41 eV NBE emission peak, two phonon replicas (peaks at 3.35 eV and 3.25 eV) are also clearly visible in FIG. 10(b). [27,28] Defect-related emission was not observed for the GaN Nanorods, such as the broadband yellow emission (with peaks at 550˜560 nm) that is frequently exhibited by GaN nanorods that are grown using various techniques.[20,28-30] The absence of defect emissions in the PL spectra and the single-crystalline structure from the TEM characterizations indicate that high-quality GaN nanorods were achieved by using the low-crystalline graphene substrates.

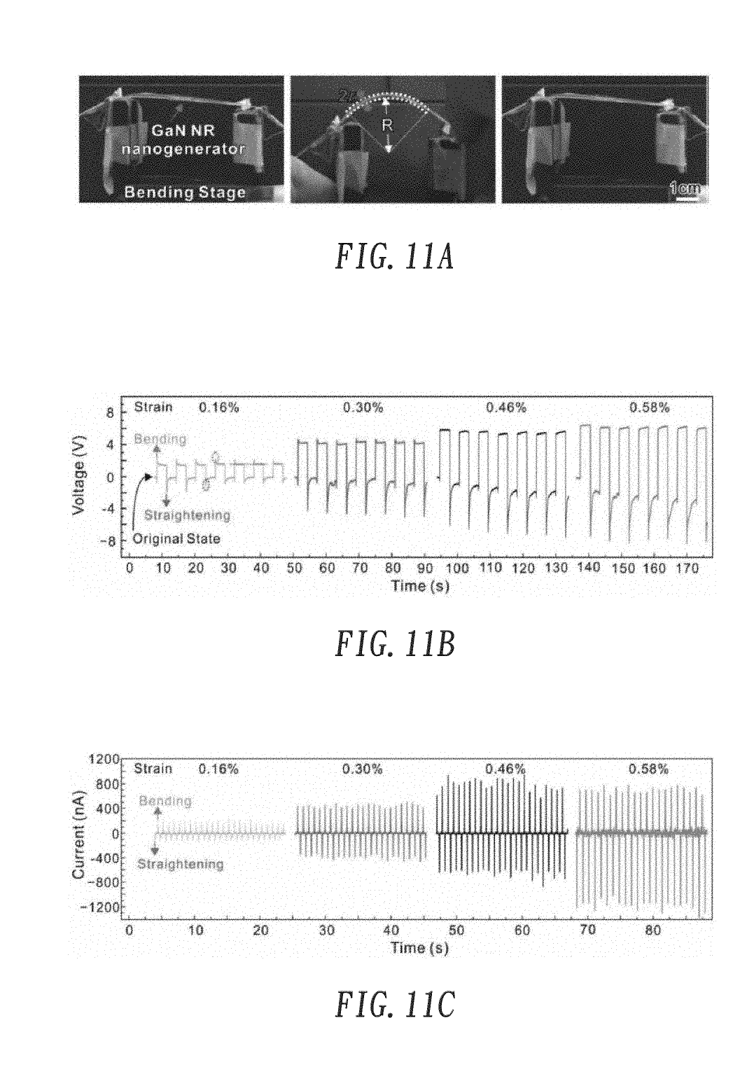

To demonstrate the functionality of the directly transferred obliquely aligned GaN nanorods under deformation, this invention constructed a transparent flexible capacitor-type flexible vertically integrated nanogenerator (VING) with an active area of ˜6 cm² containing the GaN nanorods/5 μm-thick tape sandwiched between two ITO electrodes deposited on a PET substrate, as shown in step (d) of FIG. 7A. FIG. 11A shows three distinctively different states corresponding to the original flat state, bending state, and straightening state of the nanogenerator mounted on the bending stage to generate output voltage and current. The two ends of the nanogenerator were fixed on the two walls of a linear motion stage with a spring connecting the walls. FIG. 11B is a chart illustrating the correlation between a magnified output voltage and the bending conditions of the nanogenerator shown in FIG. 11A. FIG. 11C is a chart illustrating an output voltage and current of the nanogenerator shown in FIG. 11A. In B, the open-circuit voltage under the bending state is nearly constant (dashed green line), because the piezoelectric polarization charges occurred on the top and bottom surfaces of the GaN Nanorods. Asymmetric sharp peaks from the output voltage were observed upon bending (green circle) and straightening (red circle) the device, and the negative voltage and current peaks became larger than the positive peaks as the strain increased from 0.16% to 0.58%, as shown in FIG. 11B and FIG. 11C, respectively. In the linear motion system, the bending rate became slower and straightening rate became faster as the strain increased. The asymmetric AC power peaks were attributed to the larger (smaller) shaking from the GaN nanorods in response to the faster straightening (slower bending) as the strain increased, indicating that the output peak intensity correlated well to the force profile. The maximal peak voltage and current were 8 V and 1.2 μA (0.2 μA/cm²), respectively, under the straightening force induced by the 0.58% strain. These values were ˜100-fold larger than those of the vertically oriented GaN nanorods VINGs assembled on bulk Si (111) substrates under a compressive force (0.08 V and 0.01 μA for 1 cm² active area).[32,33] The maximum output voltage and current in this embodiment were more than 6 times larger than the former best GaN nanorod VINGs under a bending force (output voltage 1.2 V, output current 40 nA), in which the nanorods were laterally aligned on flexible substrates with an uncontrolled nanorod orientation.[34] Moreover, previous experimental and simulation results revealed that obliquely bended nanorods exhibited a piezoelectric potential that was more than 2 times larger than that of lateral bended and compressed nanorods grown along the c-axis.[33,35,36] The high performance of the GaN nanorod based VING of this embodiment was partially attributed to the oblique alignment, which efficiently caused the nanorods to be bended obliquely under the bending/straightening forces. Piezoelectric VINGs using vertically aligned ZnO nanorods have been well studied, and the theoretical calculations have indicated that the piezoelectric potentials of the ZnO nanorods are ˜2.5 times larger than that for GaN nanorods based on their piezoelectric constants, Poisson ratios, Young's moduli, and relative dielectric constants.[34,35] The former best flexible ZnO Nanorods VING output a voltage of 5 V and current of 0.3 μA/cm² under a 0.12% strain using post-annealed, double-layered ZnO nanorods with a 150-nm in diameter and 2-μm length.[37] This embodiment shows results that are qualitatively in good agreement with the theoretical and experimental results [34,35,37], indicating that the epitaxy, transfer, and VING integration approaches are reliable for flexible piezoelectrics.

In summary, the embodiment of this invention is the first demonstration of simple transfer of wafer-scale single-crystalline GaN Nanorods grown on 3D oriented graphene nanosheets using handling tape without requiring a wet-etching process. The direct transfer resulted from the self-organized epitaxy of GaN nanorods on nanocrystalline 3D oriented graphene nanosheets; this method enables reducing the contact area at the interface between the GaN nanorods and 3D oriented graphene nanosheets. The oblique alignment of the GaN nanorods obtained from the textured 3D oriented graphene surface is important for inducing higher piezopotentials along nanorods during oblique bending to provide a practical functionality for piezoelectric energy harvesters and sensors. A high performance transparent, flexible, obliquely aligned nanorod-embedded piezoelectric VING was successfully fabricated. The flexible VING converted mechanical deformation into electric energy using the transferred GaN nanorods with high output voltage up to 8 V and an output current of 1.2 μA (0.2 μA/cm²). Additional levels of performance optimization of the transferred nanorods embedded flexible VING could be achieved by passivating the surfaces of the nanorods [37] and segmenting the VING using lithography [38] to prevent the current leakage through the internal structure of the nanorods. The enhanced piezoelectricity that is offered by these obliquely aligned GaN nanorods integrated on flexible substrates could offer immediate and substantial practical implications for emerging applications involving with the piezoelectronic, piezotronic and piezo-phototronic effects.[6-9,11,12]

Conditional language, such as, among others, “can,” “could,” “might,” or “may,” unless specifically stated otherwise, or otherwise understood within the context as used, is generally intended to convey that embodiments include, and in other interpretations do not include, certain features, elements and/or steps. Thus, such conditional language is not generally intended to imply that features, elements and/or steps are in any way required for one or more embodiments, or interpretations thereof, or that one or more embodiments necessarily include logic for deciding, with or without user input or prompting, whether these features, elements and/or steps are included or are to be performed in any particular embodiment.

Although specific embodiments have been illustrated and described, it will be appreciated by those skilled in the art that various modifications may be made without departing from the scope of the present invention, which is intended to be limited solely by the appended claims.

1-15. (canceled)

16. A device, comprising:
a two-dimensional (2D) material formed on a first substrate, wherein a surface morphology of the 2D material is controlled to be a three-dimensional (3D) oriented surface morphology; and
a plurality of nanostructures being randomly formed on the 3D oriented surface morphology of the 2D material and then separated from the 2D material and then transferred to a flexible substrate, resulting in the plurality of nanostructures being randomly aligned on the flexible substrate.

17. The device as set forth in claim 16, wherein the device comprises one or more stacking layers composed of photosensors, biosensors, sensors, LEDs, solar cells, vertically integrated circuits, photoelectrochemical water-splitting cells, chemical reaction cells, fuel cells, piezoelectric transistors, piezoelectric pressure sensors, nanogenerators, piezo-phototronic effect enhanced sensors, piezo-phototronic effect enhanced solar cells, piezoelectric effect enhanced photoelectrochemical water-splitting cells, or combinations thereof.

18. A device, comprising:
an array comprising one or more LEDs, sensors, solar cells, chemical reaction cells, photoelectrochemical water-splitting cell, piezoelectric transistors, piezoelectric pressure sensors, nanogenerators, or piezo-phototronic effect enhanced sensors, solar cells, or photoelectrochemical water-splitting cell, with each comprising:
a plurality of nanostructures that are formed on a 3D orientated morphology of a 2D material on a first substrate with each nanostructure having a bottom coupled to the 3D orientated morphology of the 2D material and then the plurality of nanostructures are separated from the 2D material and transferred to a second substrate or a fluid or a container;
wherein the orientations of the plurality of nanostructures disposed on the second substrate are random or are controlled to have one or more oblique angles, and wherein a diameter ratio of middle to bottom of the nanostructure ranges between 2:1 and 1000:1.

19. The device as set forth in claim 18, wherein each nanostructure comprises:
a first-type III-V or II-VI nanorod;
one or more III-V and/or II-VI and/or 2D material nanodisks and/or nanoshells and/or nanorods disposed on the first-type III-V or II-VI nanorod; and
a second-type III-V or II-VI or 2D material nanorod or nanoshell or nanodisk disposed on top of the one or more III-V and/or II-VI and/or 2D material nanodisks and/or nanoshells and/or nanorods;
wherein the first-type III-V or II-VI nanorod is n-type and the second-type III-V or II-VI or 2D material nanorod or nanoshell or nanodisk is p-type, or the first-type III-V or II-VI nanorod is p-type and the second-type III-V or II-VI or 2D material nanorod or nanoshell or nanodisk is n-type.

20. The device as set forth in claim 18, further comprising:
a plurality of pixels with each comprising one or more of the nanostructures; and
a sidewall structure comprising metal core and dielectric shell and being formed between each two pixels having different defined color.

21. The device as set forth in claim 18, further comprising:
one or more first electrodes disposed between the one or more nanostructures and the second substrate;
one or more second electrodes disposed on top of the one or more nanostructures.

22. The device as set forth in claim 18, wherein the second substrate is a flexible or transparent flexible substrate, and the device further comprises one or more second arrays stacked on the first array, each second array comprising one or more LEDs, sensors, solar cells, chemical reaction cells, photoelectrochemical water-splitting cell, piezoelectric transistors, piezoelectric pressure sensors, nanogenerators, vertically integrated circuits, or piezo-phototronic effect enhanced sensors, solar cells, or photoelectrochemical water-splitting cells.
